(19) United States
(12) Patent Application Publication
(10) Pub. No.: US 2022/0013385 A1
(43) Pub. Date: Jan. 13, 2022

(54) SUBSTRATE PROCESSING APPARATUS AND SUBSTRATE TRANSPORT METHOD

(71) Applicant: Tokyo Electron Limited, Minato-ku, Tokyo (JP)

(72) Inventors: Eiki ENDO, Nirasaki City, Yamanashi (JP); Hidetada KANEMARU, Nirasaki City, Yamanashi (JP); Yasuhiro SAITO, Nirasaki City, Yamanashi (JP); Keiichi NAGAKUBO, Nirasaki City, Yamanashi (JP); Yoshihide SAKAMOTO, Nirasaki City, Yamanashi (JP); Tomonori IWASAKI, Nirasaki City, Yamanashi (JP)

(21) Appl. No.: 17/291,713

(22) PCT Filed: Sep. 3, 2019
(86) PCT No.: PCT/JP2019/034577

§ 371 Date: May 6, 2021

(30) Foreign Application Priority Data
Nov. 14, 2018 (JP) 2018-213706

(51) Int. Cl. H01L 21/67; H01L 21/677; H01L 21/683

(52) U.S. Cl. CPC H01L 21/67201; H01L 21/67757; H01L 21/67259; H01L 21/6838; H01L 21/67294

(57) ABSTRACT

A substrate processing apparatus includes a load port, a load lock chamber, a processing module, a substrate transport mechanism, and a controller. The substrate transport mechanism includes a plurality of substrate holders, each of which is configured hold one substrate. The controller is configured to control, when the processing module is configured to process one substrate at a time, the substrate transport mechanism such that a first substrate holder transports the substrate between the load port and the processing module and a second substrate holder transports the substrate between the load lock chamber and the processing module. The controller is further configured to control, when the processing module is configured to simultaneously process the plurality of substrates, the substrate transport mechanism such that the plurality of substrate holders simultaneously transport the plurality of substrates between the load port, the load lock chamber, and the processing module.

### TECHNICAL FIELD

The present disclosure relates to a substrate processing apparatus and a substrate transport method.

### BACKGROUND

Patent Document 1 discloses a substrate transport apparatus including therein a substrate transport unit configured to transport a target substrate. According to the technique described in Patent Document 1, the substrate transport unit transports the target substrates one by one between various modules connected to the substrate transport apparatus.

### PRIOR ART DOCUMENT

### Patent Document

Patent Document 1: Japanese Laid-Open Patent Publication No. 2010-225641

### SUMMARY

The technique according to the present disclosure appropriately delivers and transports substrates in a substrate transport apparatus, thereby improving throughput.

An aspect of the present disclosure provides a substrate processing apparatus including: a load port in which a substrate accommodation container accommodating at least one substrate is placed, the load port being included in an atmospheric portion in which the substrates are processed under atmospheric pressure; a load lock chamber through which the substrates are delivered between the atmospheric portion and a decompressed portion in which the substrate is processed under a reduced pressure; a processing module configured to process the substrates in the atmospheric portion; a substrate transport mechanism configured to transport the substrates between the load port, the load lock chamber, and the processing module; and a controller configured to control operation of the substrate transport mechanism. The substrate transport mechanism includes a plurality of substrate holders, each of which is configured to hold one substrate, and the controller is configured to: control, when the processing module is configured to process one substrate at a time, the substrate transport mechanism such that a first substrate holder transports the substrate between the load port and the processing module and a second substrate holder transports the substrate between the load lock chamber and the processing module; and control, when the processing module is configured to simultaneously process the plurality of substrates, the substrate transport mechanism such that the plurality of substrate holders simultaneously transport the plurality of substrates between the load port, the load lock chamber, and the processing module.

According to the present disclosure, substrates can be appropriately delivered and transported in a substrate transport apparatus, thereby improving throughput.

### BRIEF DESCRIPTION OF DRAWINGS

FIG. 1 is a plan view illustrating an exemplary configuration of a wafer processing apparatus according to an embodiment of the present disclosure.

FIG. 2 is a side view schematically illustrating an exemplary configuration of a load lock module.

FIGS. 3A and 3B are perspective views illustrating an exemplary configuration of a wafer transport mechanism.

FIG. 4 is an explanatory view illustrating an exemplary wafer processing route in a wafer processing apparatus.

FIG. 5 is an explanatory view illustrating an exemplary wafer transport pattern according to an embodiment of the present disclosure.

FIG. 6 is an explanatory view illustrating an exemplary wafer transport pattern according to another embodiment of the present disclosure.

FIG. 7 is an explanatory view illustrating an exemplary configuration of a pick portion of a wafer transport mechanism.

FIG. 8 is an explanatory view schematically illustrating a vacuum line in a wafer transport mechanism.

FIG. 9 is an explanatory view schematically illustrating a vacuum line in a wafer transport mechanism.

FIG. 10 is an explanatory view schematically illustrating a vacuum line in a wafer transport mechanism.

FIG. 11 is a perspective view illustrating an exemplary configuration of a wafer transport mechanism according to another embodiment.

FIGS. 12A to 12D are explanatory views illustrating an exemplary operation of detecting a wafer held by a wafer transport mechanism.

### DETAILED DESCRIPTION

For example, in a semiconductor device manufacturing process, in the state in which an interior of a processing module accommodating a semiconductor wafer (a substrate. hereafter the substrate may be referred to as a “wafer”) is decompressed, various processing steps, in each of which a predetermined process is performed on the wafer, are performed. These processing steps are performed using a wafer processing apparatus provided with multiple processing modules.

The wafer processing apparatus has, for example, a configuration in which a decompressed portion configured to process or transport a wafer under a decompressed atmosphere and an atmospheric portion configured to process and transport a wafer under an atmospheric pressure atmosphere are connected to each other via a load lock module. The decompressed portion is provided with the above-mentioned multiple processing modules or the like. The atmospheric portion is provided with a loader module or the like including a wafer transport mechanism configured to transport a wafer.

As a processing module arranged in a wafer processing apparatus, a so-called double-wafer type processing module capable of processing multiple (e.g., two) wafers as a set may be used. In the double-wafer type processing module, since two wafers can be processed at the same time, it is possible to reduce the time required for wafer processing, and thus to improve throughput.

However, despite the fact that these processing modules are of a double-wafer type, the wafer transport mechanism in the related art transports one wafer at a time. For example, even in the wafer transport mechanism (a substrate transport apparatus) described in Patent Document 1, wafers are transported one by one.

That is, in a double-wafer type processing module, two wafers are processed at the same time and transported to the load lock module. However, in the wafer transport mechanism, the wafers are transported one by one. Therefore, the wafer transport mechanism needs to access the load lock module multiple times.

As described above, there is room for improving transport efficiency and throughput in a method of loading and unloading a wafer using a wafer transport mechanism for a double-wafer type processing module.

Therefore, the technique according to the present disclosure appropriately delivers and transports wafers in a wafer processing apparatus, thereby improving throughput. Specifically, the wafer transport mechanism is configured to be capable of transporting multiple wafers at the same time, and the number of wafers to be simultaneously transported by the wafer transport mechanism is determined in accordance with a situation so as to optimize the operation.

Hereinafter, the configuration of a wafer processing apparatus as a substrate processing apparatus, which implements a wafer transport method as a substrate transport method according to an embodiment, will be described with reference to the drawings. In this specification, elements having substantially the same functional configurations will be denoted by the same reference numerals, and redundant descriptions will be omitted.

<Wafer Processing Apparatus 1>

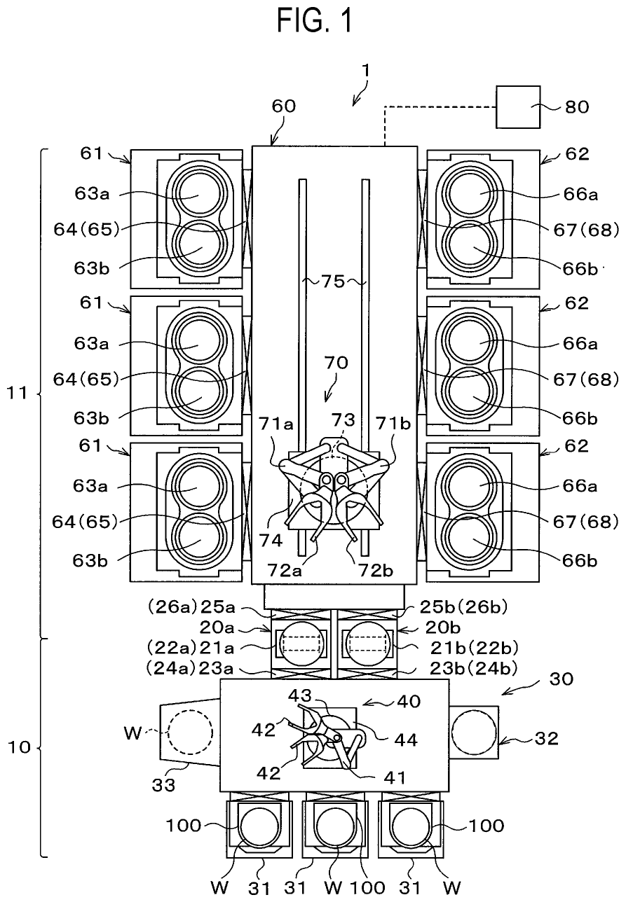

FIG. 1 is a plan view schematically illustrating the configuration of a wafer processing apparatus 1 as a substrate processing apparatus according to an embodiment of the present disclosure. In the present embodiment, the case in which the wafer processing apparatus 1 is provided with various processing modules for performing COR processing, PHT processing, CST processing, and an orientation processing on a wafer W will be described as an example. The module configuration of the wafer processing apparatus 1 is not limited thereto, and may be arbitrarily selected.

As illustrated in FIG. 1, the wafer processing apparatus 1 includes an atmospheric portion 10, a decompressed portion 11, and load lock modules 20a and 20b, and the atmospheric portion 10 and the decompressed portion 11 are integrally connected to each other via the load lock modules 20a and 20b. The atmospheric portion 10 is configured to process a wafer W under atmospheric pressure. The atmospheric portion 10 includes atmospheric processing modules configured to perform predetermined processes on a wafer W under an atmospheric pressure atmosphere, such as a CST module 32 and an orienter module 33. The decompressed portion 11 is configured to process a wafer W under reduced pressure. The decompressed portion 11 includes decompressed processing modules configured to perform predetermined processes on a wafer W in a decompressed atmosphere, such as a COR module 61 and a PHT module 62.

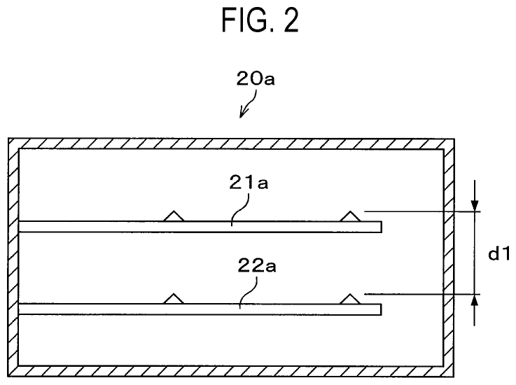

As illustrated in FIG. 2, the load lock module 20a as a load lock chamber temporarily holds and supports a wafer W in order to deliver the wafer W, which is transported from a loader module 30 (described later) in the atmospheric portion 10, to a transfer module 60 (described later) in the decompressed portion 11. The load lock module 20a includes an upper stocker 21a and a lower stocker 22a as substrate stages, which hold and support two wafers W in the vertical direction. Each of the stockers 21a and 22a is configured such that one wafer W is placed thereon. An interval (distance) d1 (e.g., the interval d1=12 mm) is provided between the upper stocker 21a and the lower stocker 22a.

As illustrated in FIG. 1, the load lock module 20a is connected to the loader module 30 via a gate 24a provided with a gate valve 23a. The load lock module 20a is connected to the transfer module 60 to be described later through a gate 26a provided with a gate valve 25a.

The load lock module 20b has the same configuration as the load lock module 20a. That is, the load lock module 20b includes an upper stocker 21a, a lower stocker 22b, a gate valve 23b and a gate 24b on the loader module 30 side, and a gate valve 25b and a gate 26b on the transfer module 60 side.

The number and arrangement of load lock modules 20a and 20b are not limited to those of the present embodiment, and may be arbitrarily set.

The atmospheric portion 10 includes: a loader module 30 including a wafer transport mechanism 40 (described later), a load port 31 including a stage on which a FOUP 100 capable of accommodating multiple wafers W in multiple stages at an equal interval (distance) d2 (e.g., the interval d2=10 mm) and transporting the wafers W is placed, the CST module (an atmospheric pressure processing module) 32 as a cooling module for cooling a wafer W, and the orienter module (atmospheric pressure processing module) 33 configured to adjust the horizontal orientation of the wafer W.

The number and arrangement of the load port 31, the CST module 32, and the orienter module 33 are not limited to those in the present embodiment, and may be arbitrarily designed.

The CST module 32 is capable of accommodating multiple wafers W (the number of which is, for example, equal to or greater than the number of wafers W accommodated in the FOUP 100) in multiple stages at equal intervals (e.g., the interval d2=10 mm), and cools the multiple wafers W.

The orienter module 33 adjusts the orientation of the wafer W in the horizontal direction from a reference position (e.g., a notch position).

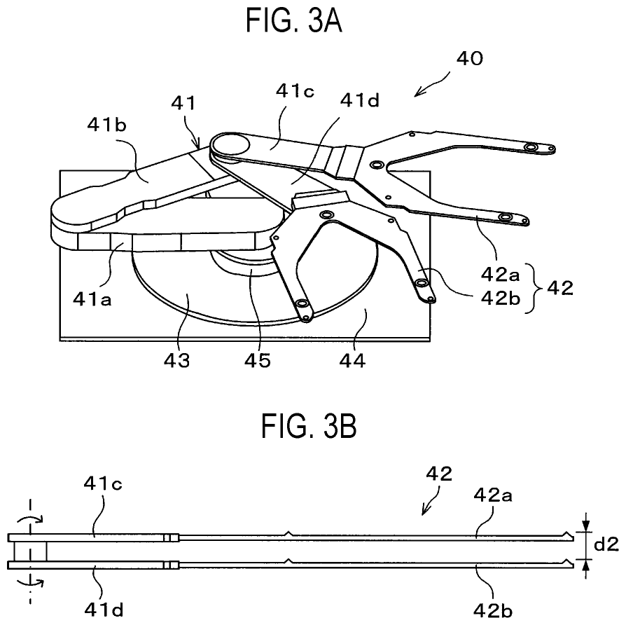

As described above, the loader module 30 has the wafer transport mechanism 40. FIG. 3A is a perspective view schematically illustrating an outline of the configuration of the wafer transport mechanism 40.

As illustrated in FIG. 1 and FIGS. 3A and 3B, the wafer transport mechanism 40 includes an arm portion 41, a pick portion 42 as a substrate holder having a wafer holding surface connected to the tip of the arm portion 41 and configured to hold the wafer W, a turntable 43 configured to rotatably support the arm portion 41, and a rotary stage 44 on which the turntable 43 is mounted. The arm portion 41 is connected to the turntable 43 via a lifting mechanism 45 capable of raising and lowering the wafer W held on the arm portion 41 in the height direction.

The arm portion 41 includes a first arm 41a, a second arm 41b, a third arm 41c, and a fourth arm 41d. One end of the first arm 41a is rotatably connected to the lifting mechanism 45. One end of the second arm 41b is rotatably connected to the other end of the first arm 41a. One end of the third arm 41c is rotatably connected to the other end of the second arm 41b, and the third arm 41c is connected to an upper picker 42a (described later). One end of the fourth arm 41d is rotatably connected to the other end of the second arm 41b, and the fourth arm 41d is connected to a lower picker 42b (described later). Each of the third arm 41c and the fourth arm 41d is connected to the other end of the second arm 41b to be independently rotatable.

The pick portion 42 has a configuration in which the upper picker (a substrate holder) 42a, which is rotatably connected to the other end of the third arm 41c and has a bifurcated fork shape, and the lower picker (a substrate holder) 42b, which is rotatably connected to the other end of the fourth arm 41d and has a bifurcated fork shape, are stacked one on another with an interval d2 (e.g., the interval d2=10 mm) therebetween. In the pick portion 42, one wafer W is placed on the top surface of the upper picker 42a, and one wafer W is further placed on the top surface of the lower picker 42b. That is, each of the pickers 42a and 42b is configured to hold one wafer W, and the wafer transport mechanism 40 is configured to hold two wafers W in multiple stages by the pick portion 42.

The wafer transport mechanism 40 is capable of transporting the wafers W between the FOUP 100 placed on the load port 31, the load lock modules 20a and 20b, the CST module 32, and the orienter module 33 by the expansion and contraction of the arm portion 41 and the rotation of the turntable 43.

The decompressed portion 11 includes the transfer module 60 configured to transport the wafer W under a decompressed atmosphere, the COR module (a decompressed processing module) 61 configured to perform COR processing on the wafer W transported from the transfer module 60 in a decompressed atmosphere, and the PHT module (a decompressed processing module) 62 as a heating module configured to perform PHT processing in a decompressed atmosphere. Multiple COR modules 61 (e.g., three) and multiple PHT modules 62 (e.g., three) are installed with respect to the transfer module 60.

As described above, the transfer module 60 is connected to the load lock modules 20a and 20b via the gate valves 25a and 25b. The transfer module 60 includes a rectangular housing therein. The wafer W carried into the load lock module 20a is transported to one COR module 61 so as to sequentially perform COR processing and PHT processing. Thereafter, the wafer W is carried out to the atmospheric portion 10 via the load lock module 20b.

Each COR module 61 performs COR processing on the wafers W placed and arranged on two stages 63a and 63b. Each COR module 61 is connected to the transfer module 60 via a gate 65 including a gate valve 64.

Each PHT module 62 performs PHT processing on the wafers W placed and arranged on two stages 66a and 66b. Each PHT module 62 is connected to the transfer module 60 via a gate 68 including a gate valve 67.

Inside the transfer module 60, a wafer transport mechanism 70 configured to transport the wafers W is installed. The wafer transport mechanism 70 includes arm portions 71a and 71b configured to hold two wafers W at multiple stage and move the two wafers W, pick portions 72a and 72b configured to hold the wafers W at the tips of the arm portions 71a and 71b, a turntable 73 configured to rotatably support the arm portions 71a and 71b, and a rotary stage 74 on which the turntable 73 is mounted. In addition, inside the transfer module 60, guide rails 75 are installed to extend in the longitudinal direction of the transfer module 60. The rotary stage 74 is installed on the guide rails 75, and the wafer transport mechanism 70 is configured to move along the guide rails 75.

Each of the pick portions 72a and 72b has a configuration in which a bifurcated fork-shaped upper picker (not illustrated) and a lower picker (not illustrated) are stacked one on another with an interval d1 (e.g., the interval d1=12 mm) therebetween. In each of the pick portions 72a and 72b, one wafer W is placed on the top surface of the upper picker, and one wafer W is further placed on the top surface of the lower picker (between the upper picker and the lower picker). That is, since each of the pick portions 72a and 72b is capable of holding two wafers W in multiple stages, the wafer transport mechanism 70 is capable of holding a total of four wafers W at the same time.

The transfer module 60 receives the wafers W held by the upper stocker 21a and the lower stocker 22a in the load lock module 20a using the pick portion 72a and transports the wafers W to the COR module 61. In addition, the pick portion 72a holds the wafers W subjected to the COR processing and transports the wafers W to the PHT module 62. In addition, the pick portion 72b holds the wafers W subjected to the PHT processing, and unloads the wafers W to the load lock module 20b.

As described above, in the wafer processing apparatus 1 of the present embodiment, the wafers W held in each module are held to be spaced apart from each other by an interval d2 (e.g., 10 mm) in the atmospheric portion 10 and to be spaced apart from each other by an interval d1 (e.g., 12 mm) in the decompressed portion 11. The 12 mm of the interval d1 and the 10 mm of the interval d2 are examples, and arbitrary intervals may be set, respectively. However, the interval d1 and the interval d2 are different from each other due to restrictions on the apparatus configuration.

The wafer processing apparatus 1 described above is installed with a controller 80. When the atmospheric processing module processes one wafer W at one time, the controller 80 is configured to control the wafer transport mechanism 40 such that the upper picker 42a transports the wafer W between the load port 31 and the atmospheric processing module, and the lower picker 42b transports the wafer W between the load lock 20a and the atmospheric processing module. Here, the case of processing one wafer W at one time includes, for example, the case in which the atmospheric processing module has a specification of processing wafers W one by one. Alternatively, the case of processing one wafer W at one time includes, for example, the case in which a sequence is set to process wafers W one by one although the atmospheric processing module is capable of process multiple wafers at the same time. When the atmospheric processing module processes multiple wafers W at the same time, the controller 80 controls the wafer transport mechanism 40 such that the pick portion 42 simultaneously transports the multiple wafers W between the load port 31, the loader module 30, and the atmospheric pressure processing module. Here, the case of processing multiple wafers W at the same time includes, for example, the case in which the atmospheric processing module has a specification capable of processing multiple wafers W at the same time. The controller 80 controls the wafer transport mechanism 40 to deliver wafers W to the load lock modules 20a and 20b one by one. When the wafer transport mechanism 40 receives multiple wafers W from the load lock module 20b, the controller 80 controls the wafer transport mechanism 40 so as to receive the wafers W on the lower picker 42b and the upper picker 42a in the order of the lower picker 42b and the upper picker 42a. When the wafer transport mechanism 40 receives multiple wafers W from the load lock module 20b, the controller 80 controls the wafer transport mechanism 40 to receive the wafers W such that identification numbers (described later) are in ascending order from the lower picker 42b toward the upper picker 42a. As will be described later, when the wafer transport mechanism 40 receives wafers W one by one, the controller 80 controls the wafer transport mechanism 40 such that after one pick portion 42 suctions and holds a wafer W, the other pick portion 42 starts suctioning a wafer W. The controller 80 is, for example, a computer, and has a program storage part (not illustrated). The program storage part stores programs for controlling processing of the wafer W in the wafer processing apparatus 1. In the program storage part, control programs for controlling various processes by a processor and programs for transporting the wafer W to each component of the wafer processing apparatus 1 in accordance with processing conditions, that is, processing recipes, are also stored. The programs may be recorded in a computer-readable storage medium, and may be installed on the controller 80 from the storage medium.

In the wafer processing apparatus 1, in addition to the controller 80, each module may be individually installed with a controller (not illustrated). That is, for example, a transport controller configured to control the operation of the wafer transport mechanism 40 may be further installed.

In the following description, each of the orienter module 33, the COR module 61, the PHT module 62, the CST module 32, and the load lock modules 20a and 20b may be referred to as a “processing module”. In addition, each of the wafer transport mechanism 40 and the wafer transport mechanism 70 may be referred to as a “transport module”.

<Wafer Processing Flow in Wafer Processing Apparatus 1>

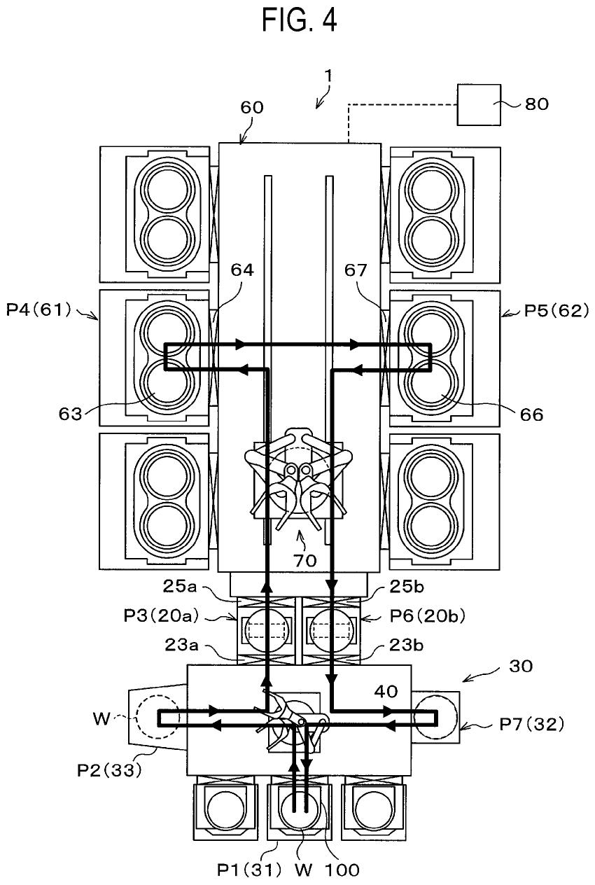

Next, wafer processing in the wafer processing apparatus 1 according to the present embodiment will be described. FIG. 4 is an explanatory view illustrating an exemplary wafer processing route in the wafer processing apparatus 1.

First, the FOUP 100 accommodating multiple wafers W is loaded into the load port 31 (position P1 in FIG. 4). When the FOUP 100 is placed in the load port 31, the controller 80 controls the wafer processing apparatus 1 to remove the wafers W from the FOUP 100 and perform a series of wafer processing steps. In the series of wafer processing steps, first, the wafer transport mechanism 40 accesses the FOUP 100, and the wafers W are removed from the FOUP 100.

The wafers W unloaded from the FOUP 100 are first transported to the orienter module 33 by the wafer transport mechanism 40 (position P2 in FIG. 4). In the orienter module 33, the orientation of the wafers W in the horizontal direction from a reference position (e.g., the notch position) is adjusted (orientation processing).

The wafers W having an adjusted horizontal orientation are loaded into the load lock module 20a by the wafer transport mechanism 40 (position P3 in FIG. 4).

Next, the wafers W are removed by the pick portion 72a of the wafer transport mechanism 70, and are loaded into the transfer module 60 from the load lock module 20a.

Next, the gate valve 64 is opened, and the pick portion 72a holding the wafers W enters the COR module 61. Then, the wafers W are placed on the stages 63a and 63b from the pick portion 72a (position P4 in FIG. 4).

Next, the gate valve 64 is closed, and COR processing is performed on the wafers W in the COR module 61.

When the COR processing in the COR module 61 is completed, the wafers W are delivered from the stages 63a and 63b to the pick portion 72a, and the wafers W are held by the pick portion 72a.

Next, the gate valve 67 is opened, and the pick portion 72a holding the wafers W enters the PHT module 62. Then, the wafers W are placed on the stages 66a and 66b from the pick portion 72a (position P5 in FIG. 4). Thereafter, the gate valve 67 is closed, and a PHT processing is performed on the wafers W.

In addition, at this time, the next wafers W are removed from the FOUP 100, loaded into the load lock module 20a via the orienter module 33, and then transported to the COR module 61 via the transfer module 60. Then, COR processing is performed on the next wafers W.

When the PHT processing is completed, the wafers W are delivered from the stages 66a and 66b to the pick portion 72b, and the wafers W are held by the pick portion 72b.

Thereafter, the gate valve 25b is opened, and the wafers W are loaded into the load lock module 20b by the wafer transport mechanism 70 (position P6 in FIG. 4). The inside of the load lock module 20b is sealed and opened to the atmosphere. Then, the gate valve 23b is opened, the wafers W are accommodated in the CST module 32 by the wafer transport mechanism 40 (position P7 in FIG. 4), and CST processing is performed, for example, for one minute.

At this time, the next wafers W on which COR processing is completed are transported to the PHT module 62 by the wafer transport mechanism 70, and PHT processing is performed thereon. In addition, further next wafers W are removed from the FOUP 100, loaded into the load lock module 20a via the orienter module 33, and then transported to the COR module 61 via the transfer module 60. Then, COR processing is performed on the further next wafers W.

When the CST processing is completed, the wafers W is are accommodated in the FOUP 100 placed in the load port 31 by the wafer transport mechanism 40 (position P1 in FIG. 4). Then, it is in a standby state until the wafer processing for all of the wafers W accommodated in the FOUP 100 is completed and the wafers W are collected into the FOUP 100.

When all of the wafers W are collected into the FOUP 100, a series of wafer processing in the wafer processing apparatus 1 is completed.

When multiple COR modules 61 and multiple PHT modules 62 are installed in the wafer processing apparatus 1 as illustrated in FIG. 1, the multiple COR modules 61 and multiple PHT modules 62 may be operated individually in parallel. That is, COR processing and PHT processing may be simultaneously performed on, for example, the wafers W, the next wafers W, and the further next wafers W.

In the wafer processing apparatus 1, it is possible to simultaneously transport and process two or more wafers W. That is, in the wafer transport mechanism 40, the wafer transport mechanism 70, the load lock modules 20a and 20b, the COR module 61, the PHT module 62, and the CST module 32, except the oriental module 33, multiple wafers W are capable of being simultaneously accommodated and processed.

<Delivery and Transport Method of Wafer W in Wafer Processing Apparatus 1>

Next, the details of delivery and transport method of the wafer W in the wafer processing apparatus 1 according to the present embodiment will be described. In delivery and transport method of the wafer W in the loader module 30 of the wafer processing apparatus 1, it is possible to selectively execute, for example, (A) a first transport pattern and (B) a second transport pattern below.

(A) The first transport pattern refers to a pattern in which, when an atmospheric processing module processes one wafer W at one time, the wafer W is transferred between the atmospheric processing module, the load lock module 20a or 20b, and the load port 31.

(B) The second transport pattern refers to a pattern in which, when an atmospheric pressure processing module processes a plurality of wafers W, the wafers W are transferred between the atmospheric pressure processing module, the load lock module 20a or 20b, and the load port 31.

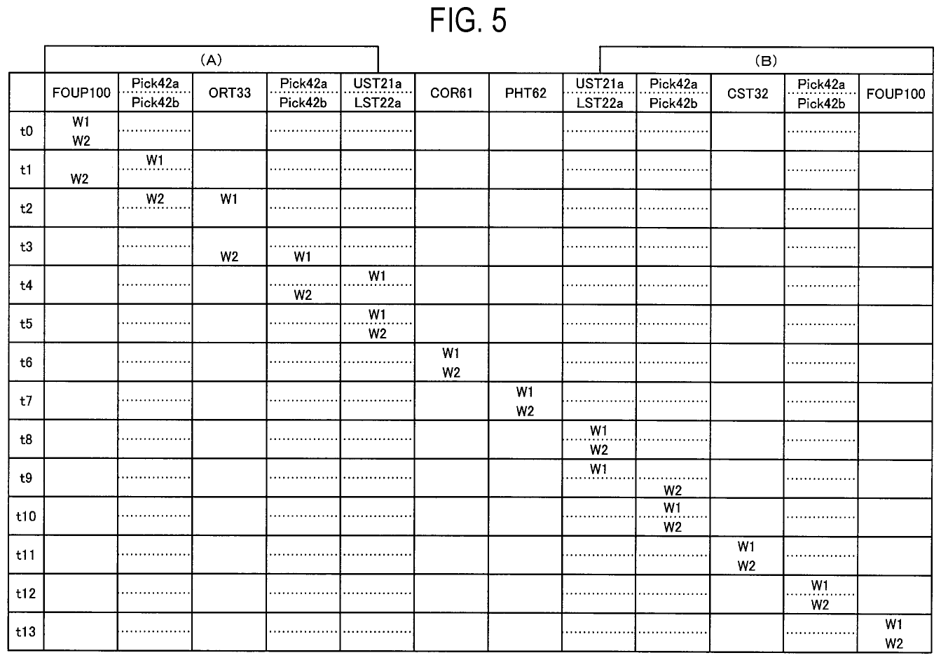

FIG. 5 is an explanatory view illustrating an example of a transport pattern of the wafer W according to the present embodiment illustrated below. With reference to FIG. 5, the case in which two wafers W1 and W2 are transported and processed will be described as an example. In FIG. 5, both the first transport pattern ((A) in FIG. 5) and the second transport pattern ((B) in FIG. 5) are performed in the loader module 30. In FIG. 5, the vertical axis “t” represents time axis in the wafer processing apparatus 1. In addition, “FOUP100” shown on the horizontal axis indicates the FOUP 100. “Pick42a” and “Pick42b” indicate the upper picker 42a and the lower picker 42b, respectively. “ORT33” indicates the orienter module 33. “UST21a” and “LST22a” indicate the upper stocker 21a and the lower stocker 22a of the load lock module 20a, respectively. “UST21b” and “LST22b” indicate the upper stocker 21b and the lower stocker 22b of the load lock module 20b, respectively. “COR61” indicates the COR module 61. “PHT62” indicates the PHT module 62. “CST32” indicates the CST module 32.

(A) First Transport Pattern

(A) in FIG. 5 illustrates a case in which an atmospheric processing module (e.g., the orienter module 33) processes one wafer W at a time while subsequent decompressed processing modules (e.g., the COR module 61 and the PHT module 62) process two wafers W at the same time. In this case, the upper picker 42a and the lower picker 42b are controlled by the controller 80 so as to share transport process of the wafer W in the atmospheric portion 10 (e.g., the transport process from the FOUP 100 to the load lock module 20a). That is, for example, the upper picker 42a as the first substrate holder is controlled to transport the wafer W between the FOUP 100 and the orienter module 33. In addition, for example, the lower picker 42b as the second substrate holder is controlled to transport the wafer W between the orienter module 33 and the load lock module 20a.

Specifically, for example, when the FOUP 100 accommodating the wafers W1 and W2 is loaded into the wafer processing apparatus 1 (time t0 in FIG. 5), the upper picker 42a holds the wafer W1 in the FOUP 100, and loads the wafer W1 into the orienter module 33 (time t1 in FIG. 5). Then, while the orienter module 33 is performing orientation processing on the wafer W1, the upper picker 42a holds the wafer W2 in the FOUP 100 and transports the wafer W2 toward the orienter module 33 (time t2 in FIG. 5). The lower picker 42b is not involved in the transport process of the wafers W1 and W2 until the orientation processing of the wafer W1 is completed (e.g., between time t0 and time t2).

When the orientation processing of the wafer W1 is completed, the lower picker 42b holds the wafer W1 in the orienter module 33 and unloads the wafer W1 from the orienter module 33. Subsequently, the upper picker 42a loads the wafer W2 into the orienter module 33. Then, while the orienter module 33 is performing orientation processing on the wafer W2, the lower picker 42b transports the wafer W1 toward the load lock module 20a (time t3 in FIG. 5).

Thereafter, when the lower picker 42b loads the wafer W1 into the upper stocker 21a of the load lock module 20a, the upper picker 42a and the lower picker 42b are in the state of not holding a wafer W, that is, a so-called free state. The state in which both the upper picker 42a and the lower picker 42b are free continues from the completion of the loading of the wafer W1 into the load lock module 20a to the completion of the orientation processing for the wafer W2. Therefore, during such a free state, the upper picker 42a and the lower picker 42b may be involved in another transport process, for example, the process of transporting a wafer W subjected to decompressed processing from the load lock module 20a to the FOUP 100. Then, when the orientation processing for the wafer W2 is completed, the lower picker 42b holds the wafer W2 in the orienter module 33, transports the wafer W2 (time t4 in FIG. 5), and loads the wafer W2 to the lower stocker 22a of the load lock module 20a (time t5 in FIG. 5). After the wafer W2 is loaded into the orienter module 33 (e.g., after time t3), the upper picker 42a is not involved in the transport process of the wafers W1 and W2.

As described above, by continuously transporting the two wafers W1 and W2 using the upper picker 42a and the lower picker 42b, it is possible to improve throughput for transporting the wafer W in the loader module 30 in which the wafer W has been transported by one transport arm in the related art. As described above, according to the first transport pattern, when transporting two wafers W, there is a time in which the upper picker 42a and the lower picker 42b are in the free state in which neither the upper picker 42a nor the lower picker 42b holds the wafer W. This makes it possible to participate in the transport of, for example, another wafer W that has been processed prior to the two wafers W, or the recovery of an erroneous wafer We generated during a processing step, and thus it is possible to improve throughput for the wafer processing step.

According to the first transport pattern, the upper picker 42a is controlled to transport the wafer W between the FOUP 100 and the orienter module 33, and the lower picker 42b is controlled to transport the wafer W between the orienter module 33 and the load lock module 20a. However, the transport pattern is not limited thereto. That is, for example, the lower picker 42b may be controlled to transport the wafer W between the FOUP 100 and the orienter module 33, and the upper picker 42a may be controlled to transport the wafer W between the orienter module 33 and the load lock module 20a.

(Wafer Transport in Decompressed Processing)

As described above, a decompressed processing module included in the decompressed portion 11 is capable of processing two wafers W1 and W2 at the same time. In such a case, two wafers W1 and W2 are transported to the decompressed processing module at the same time.

Specifically, for example, when two wafers W1 and W2 are loaded into the load lock module 20a at time t5, the wafers W1 and W2 are then held by the pick portions 72a and 72b of the wafer transport mechanism 70, simultaneously transported to each of the COR module 61, the PHT module 62, and the load lock module 20b in the order of the COR module 61, the PHT module 62, and the load lock module 20b, and simultaneously processed (time t6 to time t8 in FIG. 5).

(B) Second Transport Pattern

(B) in FIG. 5 illustrates the case in which subsequent decompressed processing modules (e.g., the COR module 61 and the PHT module 62) process two wafers W at the same time, and an atmospheric processing module (e.g., the orienter module 33) processes two wafers W at the same time. In this case, the upper picker 42a and the lower picker 42b are controlled by the controller 80 to perform transport processes of two wafers W1 and W2 in the atmospheric portion 10 (e.g., the transport processes from the load lock module 20a to the FOUP 100) at the same time.

For example, the two wafers W1 and W2, which have been subjected to decompressed processing, such as COR processing and PHT processing in the decompressed portion 11 (wafers, on which decompressed processing has been completed), are placed in the load lock module 20a. Thereafter, the upper picker 42a and the lower picker 42b simultaneously transport the two wafers W1 and W2 on which decompressed processing has been completed to the CST module 32. After the CST processing, the upper picker 42a and the lower picker 42b simultaneously transport the two wafers W1 and W2 to the FOUP 100 (time t10 to time t13 in FIG. 5).

According to the second transport pattern, it is possible to transport two wafers W1 and W2 at the same time. Therefore, it becomes possible to transport two wafers W in the loader module 30 in which the wafers W have been transported one by one in the related art, and thus it is possible to appropriately improve throughput for transporting wafers W.

As described above, according to the wafer processing apparatus 1 according to the present embodiment, in the decompressed portion 11 and the load lock modules 20a and 20b, two wafers W1 and W2 are held while being spaced apart with the interval d1 therebetween. Meanwhile, in the atmospheric portion 10, two wafers W1 and W2 are held while being spaced apart with the interval d2 therebetween. That is, the interval d1 between the adjacent stockers 21a and 22a in respective stockers in the load lock module 20a and the interval d2 between the adjacent pickers 42a and 42b in respective pickers in the atmospheric unit 10 are different from each other.

At this time, when the wafers W are delivered between modules having the same holding interval, that is, when the wafers W are delivered between modules having a holding interval of d1 or between modules having a holding interval of d2, the transport module is capable of accessing the processing module at a delivery destination while maintaining the holding interval. Thus, it is possible to deliver two wafers W at the same time.

Meanwhile, when the wafers W are delivered between modules having different holding intervals, that is, when wafers W are delivered between the load lock module 20a or 20b and the wafer transport mechanism 40, it is impossible to deliver two wafers W at the same time. For example, when the interval d1 is 12 mm and the interval d2 is 10 mm (that is, when d1>d2), the pickers 42a and 42b are not capable of simultaneously holding respective wafers W1 and W2 placed respective stockers 21a and 22a in the load lock module 20a. Therefore, even when the second transport pattern is performed by the controller 80, the two wafers W are delivered (held) one by one. Accordingly, the controller 80 controls the wafer transport mechanism 40 such that the wafer transport mechanism 40 delivers wafers W to the load lock modules 20a and 20b one by one. That is, after a first picker of the wafer transport mechanism 40 holds the first wafer W, the difference in height between the interval d1 and the interval d2 is adjusted by the lifting mechanism 45, and a second picker holds the second wafer W.

Specifically, after the two wafers W1 and W2 are loaded into the load lock module 20b (time t8 in FIG. 5), the lower picker 42b holds the wafer W2 placed on, for example, the lower stocker 22b (time t9 in FIG. 5). Thereafter, in the wafer transport mechanism 40, the height of the upper picker 42a is adjusted to the height of the upper stocker 21b by the operation of the lifting mechanism 45, and the upper picker 42a holds the wafer W1 placed on the upper stocker 21b (time t10 in FIG. 5). That is, when the plurality of wafers W is received by the wafer transport mechanism 40 from the load lock module 20a, the controller 80 controls the wafer transport mechanism 40 to sequentially receive (hold) the wafers W from the picker 42b located at the bottom portion toward the picker 42a located at the top portion.

As described above, in the wafer transport mechanism 40 according to the present embodiment, since it is possible to correct the difference in height between the interval d1 and the interval d2 by the operation of the lifting mechanism 45, it is possible to deliver the wafers W in accordance with the height difference. In adjusting the difference in height, the upper picker 42a and the lower picker 42b may be inserted into the load lock module 20b at the same time, and then the lifting mechanism 45 may be operated in the state in which the pick portion 42 is inserted. In addition, after only the lower picker 42b may be inserted to receive the wafer W2 and the lower picker 42b is then retracted, the lifting mechanism 45 may be operated to insert only the upper picker 42a.

In the above description, the control is performed such that the lower picker 42b receive the wafer W2 held by the lower stocker 22b, and then the upper picker 42a receives the wafer W1 held by the upper stocker 21b. However, the method of controlling the wafer transport mechanism 40 is not limited thereto. For example, a control may be performed such that the upper picker 42a receives the wafer W2 and the lower picker 42b receives the wafer W1. In addition, a control may be performed such that the upper picker 42a accesses the load lock module 20b first.

### Other Embodiments

The transport patterns controlled by the controller 80 in the wafer processing apparatus 1 are not limited to the examples above.

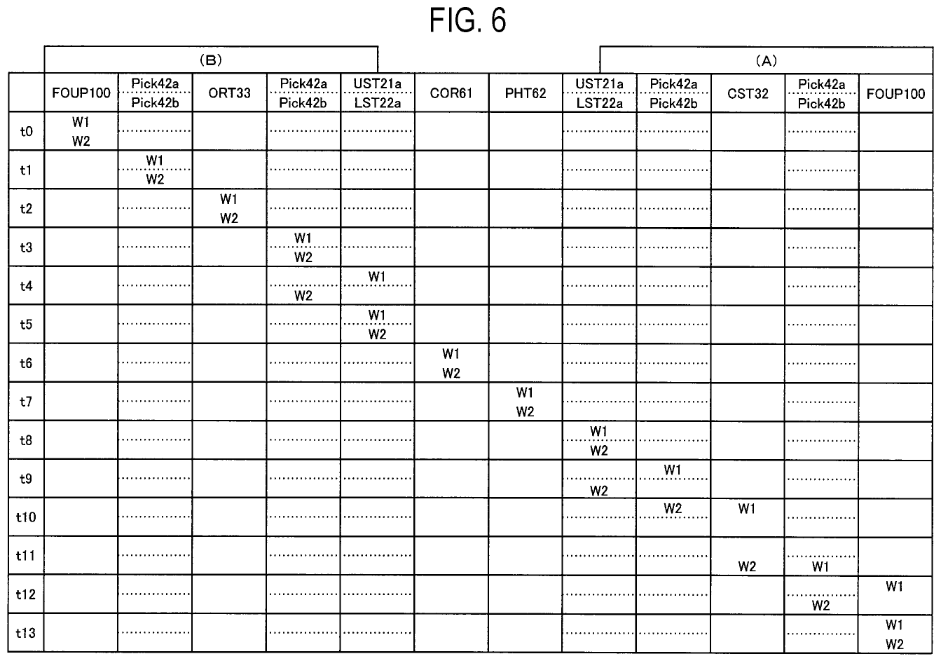

FIG. 6 is an explanatory view illustrating an exemplary transport pattern in the wafer processing apparatus 1 according to another embodiment. In this embodiment, the case where the orienter module 33 is capable of processing two wafers W at the same time is illustrated. In such a case, two wafers W unloaded from the FOUP 100 and loaded into the load lock module 20a via the oriental module 33 are capable of being simultaneously transferred and processed.

Specifically, as illustrated in (B) in FIG. 6, for example, after the wafers W1 and W2 are accommodated in the FOUP 100 and loaded into the wafer processing apparatus 1 (time t0 in FIG. 6), the wafers W1 and W2 are held by the upper picker 42a and the lower picker 42b and simultaneously transported toward the orienter module 33 (time t1 in FIG. 6).

Then, the two wafers W1 and W2, which have been subjected to orientation processing at the same time in the orienter module 33, are held by the upper picker 42a and the lower picker 42b of the wafer transport mechanism 40 again and transported toward the load lock module 20a (time t2 to time t3 in FIG. 6).

Here, as described above, the holding interval of the wafer transport mechanism 40 and the holding interval of the load lock module 20a are different from each other. Therefore, of two wafers W1 and W2 held by the wafer transport mechanism 40, first, the wafer W1 held on the upper picker 42a is delivered to the upper stocker 21a (time t4 in FIG. 6). Thereafter, in the wafer transport mechanism 40, the height of the lower picker 42b is adjusted to the height of the lower stocker 22a by the operation of the lifting mechanism 45, and the wafer W2 held by the lower picker 42b is delivered to the lower stocker 22a (time t5 in FIG. 6).

By simultaneously transporting two wafers W1 and W2 in this way, it is possible to appropriately improve throughput for transporting the wafers W.

The simultaneous transport of the two wafers W is also applicable to the case in which it is not necessary to perform orientation processing on wafers W, that is, the case in which wafers W are directly transported from the FOUP 100 to the load lock module 20a. This makes it possible to appropriately improve throughput for transporting wafers W.

In addition, in the second transport pattern described above, in order to process the two wafers W at the same time in each processing module, the wafers W are transported at the same time. However, for example, when it is necessary to transport wafers W one by one due to a defect in the module or loss of the wafer W during transport, wafers W1 and W2 may be transported one by one.

Specifically, for example, as illustrated in (A) in FIG. 6, of two wafers W1 and W2 accommodated in the load lock module 20b (time t8 in FIG. 6), first, the wafer W1 is held on the upper picker 42a (time t9 in FIG. 6), and is loaded into the CST module 32. Then, while the wafer W1 is being subjected to CST processing, the upper picker 42a, which has become empty by loading the wafer W1 into the CST module 32, holds the wafer W2 and transports the wafer W2 toward the CST module 32 (time t10 in FIG. 6).

When the CST processing of the wafer W1 is completed, the wafer W1 is held by the lower picker 42b, and then the wafer W2 is loaded into the CST module 32. Then, while the wafer W2 is being subjected to the CST processing, the wafer W1 is transported toward the FOUP 100 (time t11 in FIG. 6).

Subsequently, after the wafer W1 is loaded into the FOUP 100, the lower picker 42b, which has become empty by loading the wafer W1 into the FOUP 100, holds the wafer W2 and transports the wafer W2 toward the FOUP 100 (time t12 in FIG. 6), and then the wafer W2 is loaded into the FOUP 100 (time t13 in FIG. 6).

As described above, it is possible to arbitrarily select a transport pattern of the wafer W performed in the wafer processing apparatus 1. This makes it possible to appropriately select a transport pattern of the wafer W according to a situation of wafer processing, and thus it is possible to appropriately improve throughput for the transport of wafers W.

Then, in the wafer processing apparatus 1 according to the present embodiment, a combination of various transport patterns described above is automatically determined by the controller 80, and the wafers W are transported. In this way, since the controller 80 automatically selects an appropriate a transport pattern of the wafer W according to the situation, it is possible to more appropriately improve throughput for transport of wafers W. The above-described determination of a transport pattern may be performed for each processing module in which the wafer W is loaded or unloaded.

As described above, it is possible to arbitrarily select a transport pattern of the wafer W in the wafer processing apparatus 1. That is, in FIGS. 5 and 6, each of the first transport pattern and the second transport pattern is performed once in a transport route of the wafer W, but an example of selecting transport patterns in a combination is not limited thereto. For example, in both the first half of the transport route (performed via the orienter module 33 in (A) in FIG. 5 and (B) in FIG. 6) and the second half of the transport route (performed via the CST module 32 in (A) in FIG. 5 and (B) in FIG. 6), the first transport pattern may be selected. Of course, only the second transport pattern may be selected in both the first half and the second half of the transport route.

The above-described transport patterns may be manually selected, for example, an operator, in addition to the control by the controller 80.

In the present embodiment, the height difference in the pick portion 42 of the wafer transport mechanism 40 is adjusted by the lifting mechanism 45, but the method of adjusting the height difference is not limited thereto. For example, the interval between the upper picker 42a and the lower picker 42b of the wafer transport mechanism 40 may be adjusted by installing a mechanism for adjusting an interval of pickers (not illustrated) instead of the lifting mechanism 45. In such a case, by adjusting the picker interval, it is possible to perform two simultaneous delivery operations regardless of the holding interval of the wafers W in the processing module. Thus, it is possible to further improve throughput for wafer delivery.

In the above description, the case in which two wafers W are processed at a time has been described as an example, but the number of wafers W to be processed at the same time is not limited thereto. For example, even when three or more wafers are performed at the same time, it is possible to deliver the wafers W after correcting the height difference by the operation of the lifting mechanism 45, and thus it is possible to appropriately deliver the wafers W.

When transporting two wafers at the same time as shown in the above-mentioned transport patterns, it is preferable to perform control such that an identification number set on the wafer W held by the lower picker 42b is smaller than an identification number of the wafer W held by the upper picker 42a. That is, when transporting multiple wafers W by the same wafer transport mechanism 40, it is preferable to hold the wafers W such that the identification numbers thereof are in ascending order from the picker located at the bottom to the picker located at the top. More preferably, the identification numbers may be serial numbers in order from the bottom. That is, for example, in the example illustrated in FIG. 5, the identification number of the wafer W2 held by the lower picker 42b is preferably larger than the identification number of the wafer W1 held by the upper picker 42a.

The plurality of wafers W accommodated in multiple stages inside the FOUP 100 is generally accommodated such that the identification numbers thereof are in ascending order from the bottom. From this, even when the wafers W are transported, the wafers W are held to have the identification numbers in ascending order from the bottom, whereby it is possible to optimize the loading operation of the wafer W with respect to the FOUP 100. Further, this makes it possible to improve throughput for delivery and transport of the wafers W.

For example, in loading the wafers W into the FOUP 100, when the identification numbers of two wafers W held by the wafer transport mechanism 40 are in ascending order from the bottom and the identification numbers are serial numbers, the two wafers may be loaded at the same time (the first transport pattern). When the identification numbers are not serial numbers, the two wafers W may be continuously loaded one by one (the second transport pattern). That is, when all of the wafers W are carried into the FOUP 100, the loading of wafers W are performed such that the identification numbers are serial numbers in ascending order from the bottom inside the FOUP 100.

For the same reason as this, it is desirable to load the wafers W, which are loaded into the CST module 32 in multiple stages, in ascending order from the bottom into the CST module 32. As a result, for example, even if the identification numbers are displaced during the transport of wafers W, it is possible to optimize the loading operation of the wafer W with respect to the FOUP 100 by sorting the identification numbers in the CST module 32.

That is, when the wafers W are loaded into the CST module 32, it is possible to perform control such that, if it is possible to load the wafers W into the CST module 32 such that the identification numbers thereof are serial numbers in ascending order from the bottom, two wafers W may be loaded at the same time, and if the identification numbers are not serial numbers in ascending order, the wafers may be continuously loaded one by one. The same control applies when wafers W are unloaded from the CST module 32.

In addition, in the arrangement of the identification numbers of these wafers W, when the wafers W are accommodated such that the identification numbers are in ascending order from the top side inside the FOUP 100, a control may be performed such that the identification number of the wafer W located at the top is smaller.

When the two wafers W are delivered one by one to the wafer transport mechanism 40 as in the case of adjusting the height difference described above, it is preferable to perform control such that the two wafers W are first delivered to the lower picker 42b. That is, when multiple wafers W are delivered one by one to the same wafer transport mechanism, as illustrated at time t8 to time t10 in FIG. 5, it is preferable to place the wafers W in order from the picker located at the bottom to the picker located at the top. This makes it possible to appropriately perform a delivery operation of the wafer W with respect to the wafer transport mechanism 40, and to prevent particles from falling downward due to the delivery operation of the wafer W.

<Exemplary Configuration of Pick Portion 42>

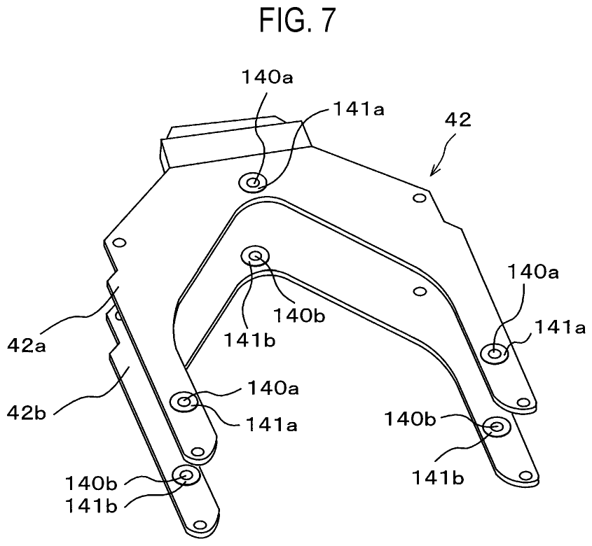

The form of holding the wafers W by the wafer transport mechanism 40 may be arbitrarily selected. For example, as illustrated in FIG. 7, each of the pickers 42a and 42b of the wafer transport mechanism 40 includes a suction holder, and each suction holder has multiple suction holes 140a and 140b. In the example illustrated in FIG. 7, the wafer placement surface of the upper picker 42a includes three suction holes 140a and three vacuum pads 141a, 141a, and 141a. In addition, the wafer placement surface of the lower picker 42b includes three suction holes 140b, 140b, and 140b and three vacuum pads 141b, 141b, and 141b. In addition, the wafer W is suctioned to and held on the placement surface by the vacuum pads 141a and 141b.

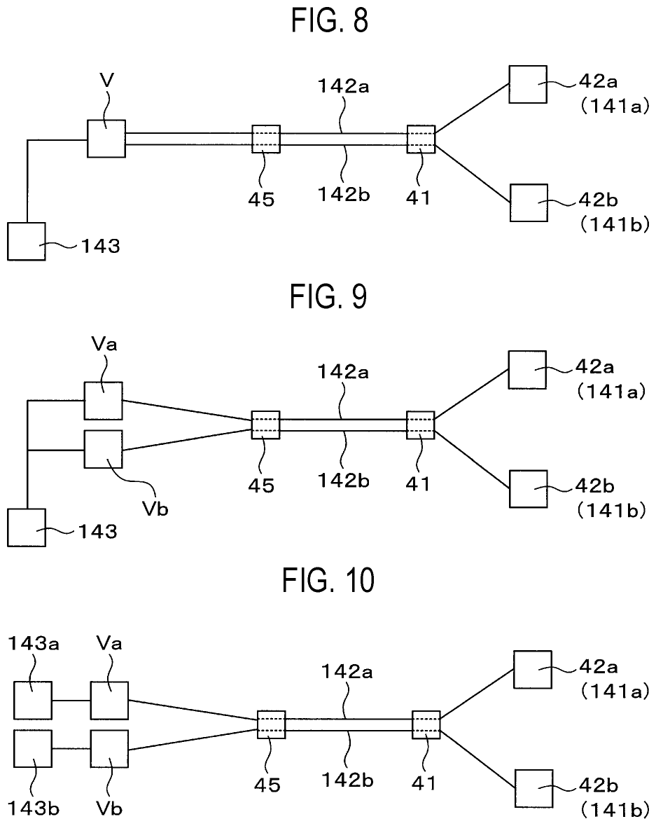

A common suction mechanism 143 is connected to each suction holder. That is, the suction mechanism 143 is connected to the suction holders of the upper picker 42a and the suction holders of the lower picker 42b. For example, as illustrated in FIG. 8, a vacuum line 142a is connected to the vacuum pads 141a formed on the upper picker 42a. In addition, a vacuum line 142b is connected to the vacuum pads 141b formed on the lower picker 42b. The vacuum lines 142a and 142b are connected to the suction mechanism 143 installed outside the wafer transport mechanism 40, via the interiors of the arm portion 41 and the lifting mechanism 45. A vacuum pump may be used as the suction mechanism 143. By operating the suction mechanism 143, the wafer transport mechanism 40 is capable of suctioning and holding the wafer W through the suction holes 140 in the vacuum pads 141. A valve V is installed in vacuum lines 142a and 142b on the downstream side of the lifting mechanism 45. With this valve V, ON/OFF of the suction of the wafer W on the upper picker 42a and ON/OFF of the suction of the wafer W on the lower picker 42b are capable of being switched.

<Countermeasure Against Non-Detection of First Wafer W>

In the case of performing the second transport pattern using the wafer transport mechanism 40 having the above-described configuration, that is, in the case of transporting two wafers W one by one, when the second wafer W is held after the first wafer W is held, the first wafer W may flip up from the pick portion 42. The present inventors have elucidated the cause of the flipping-up of the wafer W. That is, when trying to suction the second wafer W, if the first wafer W is suctioned by the suction mechanism 143 before the second wafer W is placed, a small amount of air is suctioned through the holes 140. Then, the suctioned air gives lift force to the vacuum pads 141, which holds the first wafer W. Due to this lift force, the first wafer W flips up. In addition, particularly when a deformation (for example, an upward convex shape) occurs on the first wafer W or when a deposit is attached to the suction surface of the wafer W, the wafer W is easily affected by lift force.

When lift force is applied to the wafer W in this way and the wafer W flips up, the wafer W may be damaged, or the wafer transport mechanism 40 may not be able to detect the wafer W. That is, normally, the wafer transport mechanism 40 grasps the status of holding the wafer W based on a holding pressure detected when holding the wafer W. However, the holding pressure may not be detected due to the flipping-up of the wafer W.

Methods for preventing non-detection of a wafer W may include, for example, those illustrated in the following (a) to (c).

(a) A Method of Transporting Wafers W One by One

The non-detection of the wafer W described above is concerned when, for example, the wafer transport mechanism 40 continuously delivers two wafers W one by one. Therefore, when there is a concern that the wafer W is not detected due to the flipping-up of the wafer W, for example, when the deformation of a wafer W is noticed, the transport of two wafers W by the wafer transport mechanism 40 is stopped. Then, a control is performed such that one wafer W, which may flip up, is delivered so as to be transported. As a result, since the second wafer W is not held, it is possible to prevent the first wafer W from flipping up.

(b) A Method of Controlling the Timing of Starting Suction in the Pick Portion 42 Holding the Second Wafer W

The non-detection of the wafer W described above occurs when air is suctioned from the suction holes 140 when the second wafer W is suctioned and held. Therefore, for example, as illustrated in FIG. 9, by providing valves Va and Vb in the vacuum lines 142a and 142b, respectively, it is possible to perform evacuation at an arbitrary timing. Then, the suction holding of the second wafer W is controlled such that the suction starts after the wafer W is placed on the pick portion 42, that is, the suction starts after the gap between the wafer W and the vacuum pads 141 disappears. As a result, since it is possible to prevent air from being suctioned when the suction holding of the second wafer W starts, it is possible to prevent the first wafer W from flipping up.

(c) A Method of Making the Vacuum Lines 142 of the Upper Picker 42A and the Lower Picker 42b Independent of Each Other

As illustrated in FIG. 10, suction mechanisms 143a and 143b are independently provided for the upper picker 42a and the lower picker 42b, respectively. As a result, even when air is suctioned from the suction holes 140 when the second wafer W is suctioned and held as described above, it is possible to prevent the first wafer W from flipping up.

As described above, according to three methods of preventing non-detection of the wafer W, it is possible to appropriately prevent the flipping-up of the first wafer W, which is concerned when the second wafer W is suctioned and held. In addition, it is possible to improve throughput for the delivery of the wafers W while preventing the wafer W from being undetected due to the flipping-up of the wafer W. Since it is possible to transport the wafers W by appropriately determining whether to transport two wafers W at the same time or one by one, it is possible to improve throughput for transport.

<Countermeasure Against Non-Detection of Second Wafer W>

As described above, when a deformation (e.g., an upward convex shape) occurs on the wafer W, or when a deposit is attached to the suction surface of the wafer W, the wafer transport mechanism 40 may not detect the wafer W. Normally, when an error is notified in the wafer processing apparatus 1, a series of wafer processing is interrupted, the cause of the error is confirmed, and maintenance is performed. Then, the wafer processing is initialized, and the wafer processing apparatus 1 is operated. When such an initialization operation is performed, the presence or absence of the wafer W on the wafer transport mechanism 40 is confirmed, and the operation is performed. However, even if a wafer W actually exists on the wafer transport mechanism 40, the wafer processing apparatus 1 may operate as it is, assuming that there is no wafer W due to non-detection. Then, when the wafer processing apparatus 1 operates assuming that there is no wafer W in this way, the wafer W may be damaged.

In order to prevent such non-detection of a wafer W, for example, in the initialization operation of the wafer processing apparatus 1, the presence or absence of the wafer W on the wafer transport mechanism 40 is detected using a detection sensor, such as a beam sensor (not illustrated), in addition to the above-mentioned detection of holding pressure. The detection sensor corresponds to the substrate detector according to the present disclosure.

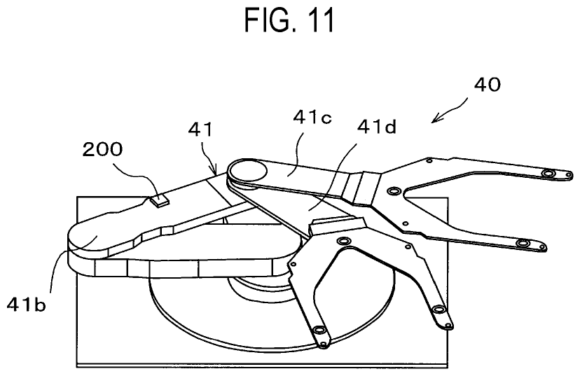

The detection sensor may be installed at an arbitrary position in the wafer processing apparatus 1. However, it is preferable to provide the detection sensor at a position where a wafer W can be detected regardless of an arm position of the wafer transport mechanism 40 at the time of initialization of the wafer processing apparatus 1. That is, for example, as illustrated in FIG. 11, a detection sensor 200 may be installed on the second arm 41b. In the following description, the case in which the detection sensor 200 is installed on the second arm 41b will be described as an example.

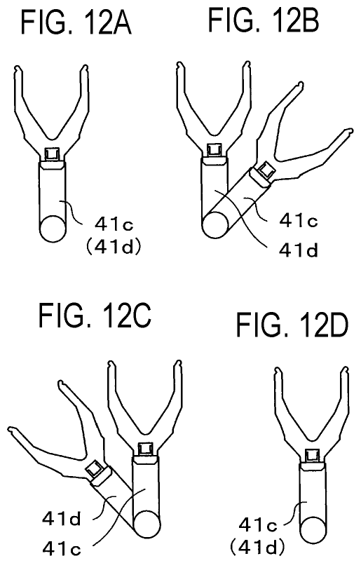

In detecting the wafer W at the time of initializing the wafer processing apparatus 1, first, as illustrated in FIG. 12A, the third arm 41c and the fourth arm 41d are arranged so as to overlap each other.

Next, as illustrated in FIG. 12B, the third arm 41c is rotated, and the situation of holding the wafer W by the third arm 41c is confirmed by the detection sensor 200. At this time, in addition to the detection of the wafer W by the detection sensor 200, the holding pressure of the third arm 41c, which is detected when the wafer W is held, is detected.

Subsequently, as illustrated in FIG. 12C, the third arm 41c and the fourth arm 41d are rotated, and the situation of holding the wafer W by the fourth arm 41d is confirmed by the detection sensor 200. At this time, in addition to the detection of the wafer W by the detection sensor 200, the holding pressure of the fourth arm 41d, which is detected when the wafer W is held, is detected. Then, when the confirmation of the situation of holding the wafer W by the third arm 41c and the fourth arm 41d is completed, the third arm 41c and the fourth arm 41d are arranged so as to overlap each other as illustrated in FIG. 12D, and the wafer W detection operation is terminated.

In the wafer W detection, when the detection result by the detection sensor 200 and the detection based on the holding pressure match in each of the third arm 41c and the fourth arm 41d, the initialization operation of the wafer processing apparatus 1 is continued. Meanwhile, when the detection result by the detection sensor 200 and the detection based on the holding pressure do not match in at least one of the third arm 41c and the fourth arm 41d, the initialization operation of the wafer processing apparatus 1 is interrupted and an error is notified.

According to the countermeasure against non-detection of the second wafer W, in addition to the detection of the wafer W based on the holding pressure, the detection of the wafer W is further performed by the detection sensor, and the operation is continued only when the results thereof match. Therefore, erroneous detection of the presence or absence of the wafer W on the arm is suppressed, and as a result, damage to the wafer W is suppressed.

The detection of the wafer W based on the holding pressure and the detection of the wafer W by the detection sensor are preferably controlled using the same controller.

According to the countermeasure against non-detection of the second wafer W, for example, by providing the detection sensor 200 on the second arm 41b, it is possible to appropriately detect the presence or absence of the wafer W regardless of the arm position of the wafer transport mechanism 40 in the wafer processing apparatus 1 at the time of initialization.

For example, by providing the detection sensor 200 on the second arm 41b, the presence or absence of the wafer on each of the arms can be easily detected only by rotating the third arm 41c and the fourth arm 41d on their positions, as illustrated in FIG. 12.

In the above description, the case where the detection sensor 200 is installed on the second arm 41b has been described as an example. However, the number and installation positions of detection sensors are not limited thereto. For example, the detection sensor may be provided on each of the upper picker 42a and the lower picker 42b, or may be provided on the first arm 41a. For example, in the above description, the case in which the detection sensor 200 is installed in the wafer transport mechanism 40 has been described as an example, but a similar detection sensor may be further installed in the wafer transport mechanism 70. The detection sensor does not necessarily have to be installed in the wafer transport mechanism, and may be installed at an arbitrary place inside the wafer processing apparatus 1.

In the above description, the case in which the countermeasure against non-detection of the second wafer W is performed at the time of initialization operation of the wafer processing apparatus 1 has been described as an example, but the countermeasure against non-detection of the second wafer W may be performed at another timing. For example, in addition to being performed at the time of initialization of the wafer processing apparatus 1, the countermeasure may be performed during maintenance of the wafer processing apparatus 1 or during a return operation after inspection.

For example, the countermeasure against non-detection of the second wafer W may be taken each time the wafer W is delivered with respect to the wafer transport mechanism. Specifically, for example, when the wafers W are loaded into or unloaded from the load lock modules 20a and 20b, the countermeasure may be performed in order to confirm whether the wafers W are delivered reliably.

It should be understood that the embodiments disclosed herein are illustrative and are not limiting in all aspects. The above embodiments may be omitted, replaced, or modified in various forms without departing from the scope and spirit of the appended claims. For example, the configuration of the wafer transport mechanism 40 is not limited to the above-described embodiments, as long as multiple wafers W can be simultaneously transported, and the holding method is not limited to suction holding.

In addition, for example, in the embodiments described above, the case in which COR processing, PHT processing, and CST processing are continuously performed on a wafer W inside the wafer processing apparatus 1 has been described as an example, but the wafer processing order on the wafer W is not limited thereto. Furthermore, the processes performed inside the wafer processing apparatus 1 are not limited to those described above, and, for example, an etching process may be performed.

The following configurations also fall within the technical scope of the present disclosure.

(1) A substrate processing apparatus including: a load port in which a substrate accommodation container accommodating at least one substrate is placed, the load port being included in an atmospheric portion in which the substrates are processed under atmospheric pressure; a load lock chamber through which the substrates are delivered between the atmospheric portion and a decompressed portion in which the substrate is processed under a reduced pressure; a processing module configured to process the substrates in the atmospheric portion; a substrate transport mechanism configured to transport the substrates between the load port, the load lock chamber, and the processing module; and a controller configured to control operation of the substrate transport mechanism, wherein substrate transport mechanism includes a plurality of substrate holders, each of which is configured to hold one substrate, and the controller is configured to: control, when the processing module is configured to process one substrate at a time, the substrate transport mechanism such that a first substrate holder transports the substrate between the load port and the processing module and a second substrate holder transports the substrate between the load lock chamber and the processing module; and control, when the processing module is configured to simultaneously process the plurality of substrates, the substrate transport mechanism such that the plurality of substrate holders simultaneously transport the plurality of substrates between the load port, the load lock chamber, and the processing module.

(2) The substrate processing apparatus of item (1) above, wherein the plurality of substrate holders is installed in a vertical direction, the load lock chamber includes a plurality of substrate stages installed in the vertical direction, one substrate is placed on each substrate stage, a distance between adjacent substrate stages in respective substrate stages and a distance between adjacent substrate holders in respective substrate holders are different from each other, and the controller is further configured to control the substrate transport mechanism to deliver the substrates to the load lock chamber one by one.

According to items (1) and (2) above, it is possible to arbitrarily select the substrate wafer pattern according to the processing number and holding interval of substrates in the substrate processing apparatus. Therefore, it is possible to improve throughput for wafer transport.

(3) The substrate processing apparatus of item (2) above, the controller is configured to control the substrate transport mechanism such that, when the plurality of substrates is received from the load lock chamber by the substrate transport mechanism, the substrate transport mechanism receives the substrates sequentially from the substrate holder located at the bottom toward the substrate holder located at the top.

(4) The substrate processing apparatus of item (2) or (3), wherein identification numbers are set for the plurality of substrates, respectively, and the controller is configured to control the substrate transport mechanism such that, when the plurality of substrates is received from the load lock chamber by substrate transport mechanism, the substrate transport mechanism receives the substrates such that the identification numbers are in ascending order from the substrate holder located at the bottom toward the substrate holder located at the top.

According to items (3) and (4) above, it is possible to appropriately control the order of the substrates held by the substrate transport mechanism, whereby it is possible to efficiently deliver the substrates to the substrate accommodation container. As a result, it is possible to improve throughput for substrate delivery.

(5) The substrate processing apparatus of any one of items (1) to (4) above, wherein each substrate holder includes a suction holder configured to suction and hold a substrate, and the suction holder includes a plurality of suction holes.

(6) The substrate processing apparatus of item (5) above, wherein a common suction mechanism is connected to each suction holder.

(7) The substrate processing apparatus of item (6) above, wherein the controller is configured to control the substrate transport mechanism such that, when the substrate are received one by one from the processing module by the substrate transport mechanism, after one substrate holder suctions and holds a substrate, another substrate holder starts suctioning a substrate.

(8) The substrate processing apparatus of (5) above, wherein a separate suction mechanism is connected to each of the plurality of substrate holders such that each of the plurality of substrate holders independently suctions and holds the substrate.

According to items (5) to (8) above, it is possible to appropriately prevent flipping-up of a previous substrate caused due to the suction and holding of the substrate. As a result, it is possible to appropriately perform substrate delivery.

(9) The substrate processing apparatus of any one of items (1) to (8) above, wherein the processing module includes an atmospheric processing module configured to perform processing under atmospheric pressure, and the atmospheric processing module is at least one of an orienter module configured to adjust horizontal orientation of the substrate and a cooling module configured to perform cooling processing on the substrate.

(10) The substrate processing apparatus of any one of items (1) to (9), wherein the decompressed portion includes a decompressed processing module configured to perform processing under decompressed pressure, the decompressed processing module is at least one of a COR module configured to perform COR processing on the substrate and a heating module configured to heat the substrate, and the COR module and the heating module are configured to simultaneously process multiple substrates.

(11) The substrate processing apparatus of any one of items (1) to (10), further including: a substrate detector configured to detect presence or absence of the substrate on the substrate holder.

(12) The substrate processing apparatus of item (11) above, wherein the substrate detector is installed on the substrate transport mechanism.

(13) A substrate transport method performed in a substrate processing apparatus which includes: a load port in which a substrate accommodation container accommodating at least one substrate is placed, the load port being included in an atmospheric portion in which the substrates are processed under atmospheric pressure; a load lock chamber through which the substrates are delivered between the atmospheric portion and a decompressed portion in which the substrate is processed under a reduced pressure; a processing module configured to process the substrates in the atmospheric portion; and a substrate transport mechanism configured to transport the substrates between the load port, the load lock chamber, and the processing module, the substrate transport mechanism including a plurality of substrate holders, each of which is configured to hold one substrate. The substrate transport method includes: when the processing module is configured to process one substrate at a time, transporting the substrate between the load port and the processing module using a first substrate holder; and transporting the substrate between the load lock chamber and the processing module using a second substrate holder, and when the processing module is configured to simultaneously process a plurality of substrates, simultaneously transporting the plurality of substrates between the load port, the load lock chamber, and the processing module using the plurality of substrate holders.

(14) The substrate transport method of item (13) above, further including detecting presence or absence of the substrate held by the substrate holder.

### EXPLANATION OF REFERENCE NUMERALS

1: wafer processing apparatus, 10: atmospheric portion, 11: decompressed portion, 20: load lock module, 30: loader module, 31: load port, 32: CST module, 33: orienter module, 40: wafer transport mechanism, 42: pick portion, 42a: upper picker, 42b: lower picker, 80: controller, 100: FOUP, W: wafer

1-14. (canceled)

15. A substrate processing apparatus comprising:
a load port in which a substrate accommodation container accommodating at least one substrate is placed, the load port being included in an atmospheric portion in which the substrates are processed under atmospheric pressure;
a load lock chamber through which the substrates are delivered between the atmospheric portion and a decompressed portion in which the substrate is processed under a reduced pressure;
a processing module configured to process the substrates in the atmospheric portion;
a substrate transport mechanism configured to transport the substrates between the load port, the load lock chamber, and the processing module; and
a controller configured to control operations of the substrate transport mechanism,
wherein the substrate transport mechanism includes a plurality of substrate holders, each of which is configured to hold one substrate, and
wherein the controller is configured to:
control, when the processing module is configured to process one substrate at a time, the substrate transport mechanism such that a first substrate holder transports the substrate between the load port and the processing module and a second substrate holder transports the substrate between the load lock chamber and the processing module; and
control, when the processing module is configured to simultaneously process a plurality of substrates, the substrate transport mechanism such that the plurality of substrate holders simultaneously transport the plurality of substrates between the load port, the load lock chamber, and the processing module.

16. The substrate processing apparatus of claim 15, wherein the plurality of substrate holders is installed in a vertical direction,
the load lock chamber includes a plurality of substrate stages installed in the vertical direction, one substrate is placed on each substrate stage,
a distance between adjacent substrate stages in respective substrate stages and a distance between adjacent substrate holders in respective substrate holders are different from each other, and
the controller is further configured to control the substrate transport mechanism to deliver the substrates to the load lock chamber one by one.

17. The substrate processing apparatus of claim 16, wherein the controller is configured to control the substrate transport mechanism such that, when the plurality of substrates is received from the load lock chamber by the substrate transport mechanism, the substrate transport mechanism receives the substrates sequentially from the substrate holder located at a bottom position toward the substrate holder located at a top position.

18. The substrate processing apparatus of claim 17, wherein identification numbers are set for the plurality of substrates, respectively, and
the controller is configured to control the substrate transport mechanism such that, when the plurality of substrates is received from the load lock chamber by the substrate transport mechanism, the substrate transport mechanism receives the substrates such that the identification numbers are in ascending order from the substrate holder located at a bottom position toward the substrate holder located at a top position.

19. The substrate processing apparatus of claim 18, wherein each substrate holder includes a suction holder configured to suction and hold the substrate, and the suction holder includes a plurality of suction holes.

20. The substrate processing apparatus of claim 19, wherein a common suction mechanism is connected to each suction holder.

21. The substrate processing apparatus of claim 20, wherein the controller is configured to control the substrate transport mechanism such that, when the substrates are received one by one from the processing module by the substrate transport mechanism, after one substrate holder suctions and holds a first substrate, another substrate holder starts suctioning a second substrate.

22. The substrate processing apparatus of claim 21, wherein the processing module includes an atmospheric processing module configured to perform processing under atmospheric pressure, and
the atmospheric processing module is at least one of an orienter module configured to adjust horizontal orientation of the substrate and a cooling module configured to perform cooling processing on the substrate.

23. The substrate processing apparatus of claim 22, wherein the decompressed portion includes a decompressed processing module configured to perform processing under decompressed pressure,
the decompressed processing module is at least one of a COR module configured to perform COR processing on the substrate and a heating module configured to perform heat the substrate, and
the COR module and the heating module are configured to simultaneously process the plurality of substrates.

24. The substrate processing apparatus of claim 23, further comprising:
a substrate detector configured to detect presence or absence of the substrate on the substrate holder.

25. The substrate processing apparatus of claim 24, wherein the substrate detector is installed on the substrate transport mechanism.

26. The substrate processing apparatus of claim 19, wherein a separate suction mechanism is connected to each of the plurality of substrate holders such that each of the plurality of substrate holders independently suctions and holds the substrate.

27. The substrate processing apparatus of claim 16, wherein identification numbers are set for the plurality of substrates, respectively, and
the controller is configured to control the substrate transport mechanism such that, when the plurality of substrates is received from the load lock chamber by the substrate transport mechanism, the substrate transport mechanism receives the substrates such that the identification numbers are in ascending order from the substrate holder located at a bottom position toward the substrate holder located at a top position.

28. The substrate processing apparatus of claim 15, wherein each substrate holder includes a suction holder configured to suction and hold the substrate, and the suction holder includes a plurality of suction holes.

29. The substrate processing apparatus of claim 15, wherein the processing module includes an atmospheric processing module configured to perform processing under atmospheric pressure, and
the atmospheric processing module is at least one of an orienter module configured to adjust horizontal orientation of the substrate and a cooling module configured to perform cooling processing on the substrate.

30. The substrate processing apparatus of claim 15, wherein the decompressed portion includes a decompressed processing module configured to perform processing under decompressed pressure,
the decompressed processing module is at least one of a COR module configured to perform COR processing on the substrate and a heating module configured to perform heat the substrate, and
the COR module and the heating module are configured to simultaneously process the plurality of substrates.

31. The substrate processing apparatus of claim 15, further comprising:
a substrate detector configured to detect presence or absence of the substrate on the substrate holder.

32. A substrate transport method performed in a substrate processing apparatus, which includes: a load port in which a substrate accommodation container accommodating at least one substrate is placed, the load port being included in an atmospheric portion in which the substrates are processed under atmospheric pressure; a load lock chamber through which the substrates are delivered between the atmospheric portion and a decompressed portion in which the substrate is processed under a reduced pressure; a processing module configured to process the substrates in the atmospheric portion; and a substrate transport mechanism configured to transport the substrates between the load port, the load lock chamber, and the processing module, the substrate transport mechanism including a plurality of substrate holders, each of which is configured to hold one substrate, the substrate transport method comprising:
when the processing module is configured to process one substrate at a time, transporting the substrate between the load port and the processing module using a first substrate holder, and transporting the substrate between the load lock chamber and the processing module using a second substrate holder; and
when the processing module is configured to simultaneously process a plurality of substrates, simultaneously transporting the plurality of substrates between the load port, the load lock chamber, and the processing module using the plurality of substrate holders.

33. The substrate transport method of claim 32, further comprising:
detecting presence or absence of the substrate held by the substrate holder.
